(19) United States
(12) Patent Application Publication
(10) Pub. No.: US 2017/0365675 A1
(43) Pub. Date: Dec. 21, 2017

(54) DUMMY PATTERN ARRANGEMENT AND METHOD OF ARRANGING DUMMY PATTERNS

(71) Applicant: UNITED MICROELECTRONICS CORP., Hsin-Chu City (TW)

(72) Inventors: Ching-Yu Chang, Taipei City (TW); Ying-Chiao Wang, Changhua County (TW); Hon-Huei Liu, Kaohsiung City (TW); Jyh-Shyang Jenq, Pingtung County (TW); Chung-Liang Chu, Kaohsiung City (TW); Yu-Ruei Chen, New Taipei City (TW)

(21) Appl. No.: 15/183,800

(22) Filed: Jun. 16, 2016

(51) Int. Cl. H01L 29/423; H01L 21/3205; H01L 21/3213; H01L 27/02

(52) U.S. Cl. CPC H01L 29/4238; H01L 27/0207; H01L 21/32055; H01L 21/32139

(57) ABSTRACT

A dummy pattern arrangement and a method of arranging dummy patterns are provided in the present invention. The dummy pattern arrangement includes a substrate with a dummy region, a plurality of first base dummy cells arranged spaced apart from each other along a first direction in the dummy region, and two first edge dummy cells arranged respectively at two opposite sides of the first base dummy cells along the first direction in the dummy region.

### BACKGROUND OF THE INVENTION

### 1. Field of the Invention

The present invention relates to a dummy pattern arrangement and a method of arranging dummy patterns. More particularly, the present invention relates to a flexible dummy pattern arrangement with extended dummy cells.

### 2. Description of the Prior Art

The integrated circuit (IC) design is more challenging when semiconductor technologies are continually progressing to smaller feature sizes, such as 45 nanometers, 28 nanometers, and below. The performance of a chip design is seriously influenced by the control of resistance/capacitance (RC), timing, leakage, and topology of the metal/dielectric inter-layers. Those are further related to resolution of the lithography patterning and the imaging accuracy.

To enhance the imaging effect when a design pattern is transferred to a wafer, an optical proximity correction (OPC) to minimize the proximity effect is indispensable. Assist features are added to an IC pattern to improve the imaging resolution of the IC pattern during a lithography patterning process.

In another aspect, during the semiconductor fabrication, a chemical mechanical polishing (CMP) process is applied to the wafer for polishing back and globally planarizing the wafer surface. CMP involves both mechanical grinding and chemical etching in the material removal process. However, because the removal rates of different materials (such as metal and dielectric material) are usually different, polishing selectivity leads to undesirable dishing and erosion effects. Dishing occurs when the copper recedes below or protrudes above the level of the adjacent dielectric. Erosion is a localized thinning of the dielectric. In this case, dummy features are inserted into the IC pattern to enhance the CMP performance.

However, along with the progress of semiconductor technology, the feature sizes are getting smaller and smaller. The existing methods to add various dummy features have limited degree of freedom and effectiveness to tune the pattern density and poor uniformity of the pattern density. This presents more issues, such as spatial charging effect and micro-loading effect, when an electron-beam lithography technology is used to form the IC pattern. Furthermore, during the process to insert dummy features, various simulations and calculations associated with the dummy features take more time, causing the cost to increase.

Therefore, what is needed is a method for IC design and mask making to effectively and efficiently adjusting an IC pattern to address the above issues.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

It is a novel concept to provide a dummy pattern arrangement with inner base dummy cells and outer edge dummy cells in two axis directions. The base dummy cells may be extended by a number based on the distance between the two edge dummy cells. The edge dummy cell provides wider and solid dummy patterns at the edge adjacent to circuit regions.

In one aspect of the embodiments, there is provided a dummy pattern arrangement in a semiconductor device. The dummy pattern arrangement includes a substrate with a dummy region, a plurality of first base dummy cells arranged spaced apart from each other along a first direction in the dummy region, and two first edge dummy cells arranged respectively at two opposite sides of the first base dummy cells along the first direction in the dummy region.

In another aspect of the embodiments, there is provided a method of arranging dummy patterns in semiconductor devices, The method includes the steps of defining a dummy region on a substrate, and forming dummy patterns in the dummy region, wherein the dummy patterns include a plurality of first base dummy cells arranged spaced apart from each other along a first direction and a plurality of first edge dummy cells at two opposite sides of the first base dummy cells along the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Features will become apparent to those of ordinary skill in the art by describing in detail exemplary embodiments with reference to the attached drawings, in which:

FIG. 1 is a schematic top view of a dummy cell arrangement filling up a dummy region in accordance with one embodiment of the present invention;

FIG. 2 is a schematic top view of the dummy patterns in dummy cells of a row dummy region in accordance with one embodiment of the present invention;

FIG. 3 is a schematic top view of the dummy patterns in dummy cells of a column dummy region in accordance with one embodiment of the present invention;

FIG. 4 is a flow chart of a method of arranging dummy patterns in semiconductor devices in accordance with one embodiment of the present invention;

FIG. 5 is a flow chart of a method of arranging dummy patterns in semiconductor devices in accordance with an alternative embodiment of the present invention;

FIG. 6 is a top view schematically illustrating a step of defining a dummy region adjacent to circuit regions in accordance with one embodiment of the present invention;

FIG. 7 is a top view schematically illustrating a step of dividing the dummy region into a row dummy region and a column dummy region in accordance with one embodiment of the present invention;

FIG. 8 is a top view schematically illustrating a step of dividing the dummy region into multiple row regions and multiple column regions in accordance with one embodiment of the present invention;

FIG. 9 is a top view schematically illustrating a step of defining edge dummy cells respectively at two opposite edges of each column region and each row region in accordance with one embodiment of the present invention; and

FIG. 10 is a top view schematically illustrating a step of defining a row and a column of base dummy cells between two edge dummy cells in each row region and column region in accordance with one embodiment of the present invention.

### DETAILED DESCRIPTION

Advantages and features of embodiments may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations of embodiments to those skilled in the art, so embodiments will only be defined by the appended claims. Like reference numerals refer to like elements throughout the specification.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the following discussion it should be understood that formation of the dummy layer and/or dummy patterns filled on a substrate refers to the patterns on the processing reticle as well as the features transferred from the reticle to the semiconductor substrate which subsequently receives the patterns. Those dummy patterns may be sub-resolution features for optical proximity correction (OPC) to enhance the pattern density and pattern uniformity, or the supporting features to enhance the CMP performance.

Moreover, it should be understood that a drawn layer is drawn by a circuit designer. Alternatively, an extracted layer is generally formed at pattern generation as a function of the drawn layer and may not be an electrically functional part of the circuit. The relevant components in OPC technique for arranging the dummy pattern, for example data input/output, image memory or the processing unit, will not be described in the embodiment. Similarly, the relevant tools, process or the material in the semiconductor manufacture will not be described in the embodiment too. Both these two contents are not essential and distinctive features and approaches to the dummy pattern arrangement in the present invention.

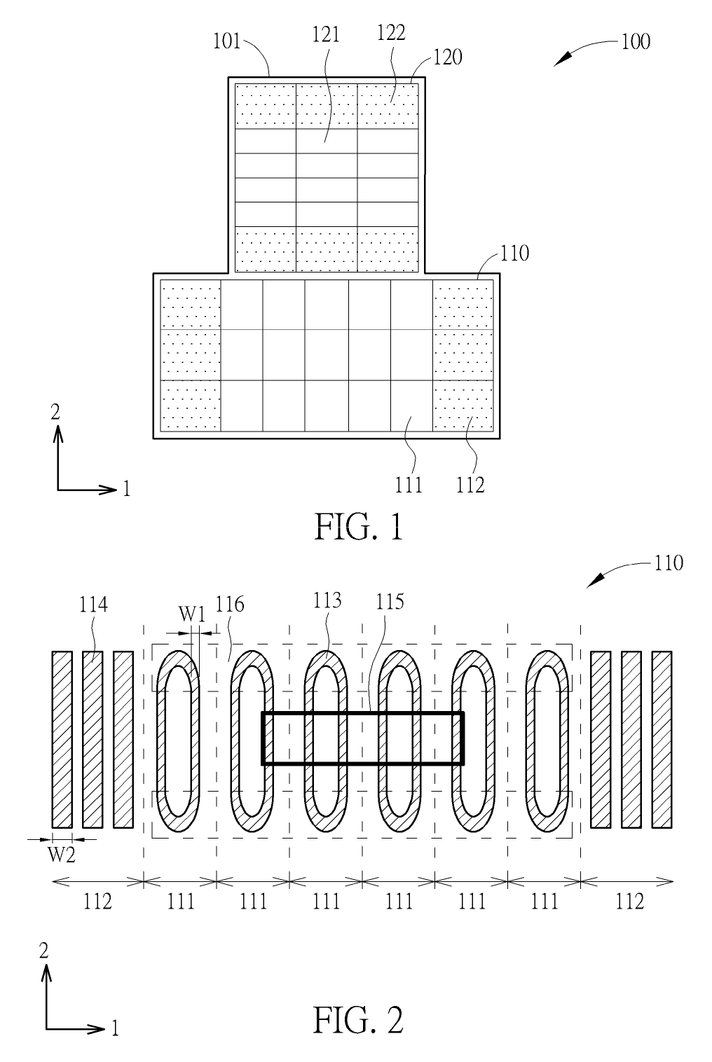

Hereinafter, a dummy pattern arrangement according to one embodiment of the present invention will be first described with reference to FIGS. 1 to 3, which are top views schematically showing the arrangement of dummy cells and corresponding dummy patterns structure in the dummy cells. In FIGS. 1 to 3, some components are enlarged, reduced in size, or omitted for easy understanding and preventing obscuring the subject matters of the present invention.

First, please refer to FIG. 1, which is a top view schematically illustrating a dummy cell arrangement filling up a dummy region according to one embodiment of the present invention. A dummy region 101 for placing/filling the dummy cell is first defined on a substrate 100. The dummy region 101 may be defined based on adjacent circuit regions (not shown). For example, the substrate 100 may first be included and set with multiple circuit regions for semiconductor devices. The remaining region on the substrate 100 may all be defined as the dummy region 101 in order to increase the pattern density and improve the pattern uniformity. The embodiment provides a dummy region 101 with an exemplary inverted-T shape. It should be known for those ordinary skilled in the art that the dummy region 101 may have an irregular shape that filling up the blank surface on the substrate 100.

In the embodiment, the dummy region 101 is divided into a plurality of row regions 110 and column regions 120. Each row region 110 is included with a plurality of first base dummy cells 111 arranged along a first direction 1 (i.e. the row direction) and two first edge dummy cells 112 arranged respectively at two opposite sides of the plurality of first base dummy cells 111 along the first direction 1. Similarly, each column region 120 is included with a plurality of second base dummy cells 121 arranged along a second direction 2 (i.e. the column direction) and two second edge dummy cells 122 arranged respectively at two opposite sides of the plurality of second base dummy cells 121 along the second direction 2. The first base dummy cells 111, the first edge dummy cells 112, the second base dummy cells 121 and the second edge dummy cells 122 are arranged in rows 110 and columns 120 so that the dummy region 101 is filled up with dummy cell to achieve an optimized pattern density. In the present invention, the first and second edge dummy cell 112, 122 are fixed dummy cells arranged at an edge of the dummy region 101, and more specifically, adjacent to a circuit region (not shown).

The term “dummy cell” used in the embodiment is a dummy unit to be arranged and fill up the region. More specifically, the base dummy cell is inner dummy cell which may be arranged in a row or in a column to fill the row region 110 and column region 120, while the edge dummy cell is the dummy cell at both outermost sides of the row region 110 and the column region 120 in their longitudinal directions. The base dummy cell and edge dummy cell are also different in their dummy patterns, which will be explicitly described in following embodiments.

Please refer to FIG. 2, which is a schematic top view of dummy patterns arranged in the dummy cells of a row region 110 according to one embodiment of the present invention. An exemplary row region 110 with three inner first base dummy cells 111 and two outermost first edge dummy cells 112 is provided in the embodiment to explicitly describe the dummy pattern arrangement of the present invention. Please note that the number of the first base dummy cells 111 may be different depending on, for example, the length of the row region 110, the dummy pattern density, or the dimension of underlying active region to be overlapped.

As shown in FIG. 2, each first base dummy cell 111 includes a plurality of line patterns 113 spaced apart from each other along the first (row) direction 1 and extending along the second (column) direction 2, but not limited thereto. In the embodiment, the line patterns 113 in the figure is depicted in a closed loop form since it is formed by sidewall image transfer (SIT) technology in the example. In SIT process, a plurality of mandrels (not shown) are formed first on the substrate in the position corresponding to the loop center. A spacer is then formed surrounding the mandrel to serve as a sub-resolution mask, which will be transferred into patterns of gate line or fin for multi-gate structure in later photolithographic process. Through the SIT technology, thinner features may be patterned on the substrate beyond the limit of current photolithography. In the embodiment, the loop patterns formed by SIT may be further trimmed by providing an etch mask with slot opening 116 exposing the rounded, connected portion of the loop pattern and performing an etching process to remove the portions, so that each loop pattern is divided into two line patterns 113.

In the embodiment, the line patterns 113 are exemplarily assumed as the poly-Si lines for gate structures. In this case, the number of the first base dummy cells 111 filled in a row region 110 highly depends on the dimensions of the underlying active fin region 115. The poly-Si gate lines would traverse across the fins (not shown) in fin regions 115 in perpendicular orientation. For this reason, the first base dummy cells 111 are configured to cover the whole fin region 115. The fin regions 115 with longer length in row direction 1 would require more first base dummy cells 111 arranged in row direction 1 to cover thereon.

The line patterns 114 in two outermost first edge dummy cells 112 may be formed in the same process (ex. SIT) with the line patterns 114 of first base dummy cells 111, but with a larger width W2 than the one of line patterns 113 (width W1) to provide fixed and solid dummy features between the dummy region 101 and the circuit region. For example, the line patterns 114 of first edge dummy cells 112 may be defined by an additional mask after the line patterns 113 of first base dummy cells 111 is defined by the spacer surrounding the mandrel. In the embodiment, each first base dummy cell 111 includes a plurality of line patterns 113 spaced apart from each other along the first (row) direction 1 and extending along the second (column) direction 2, just like the line patterns 113, but not limited thereto.

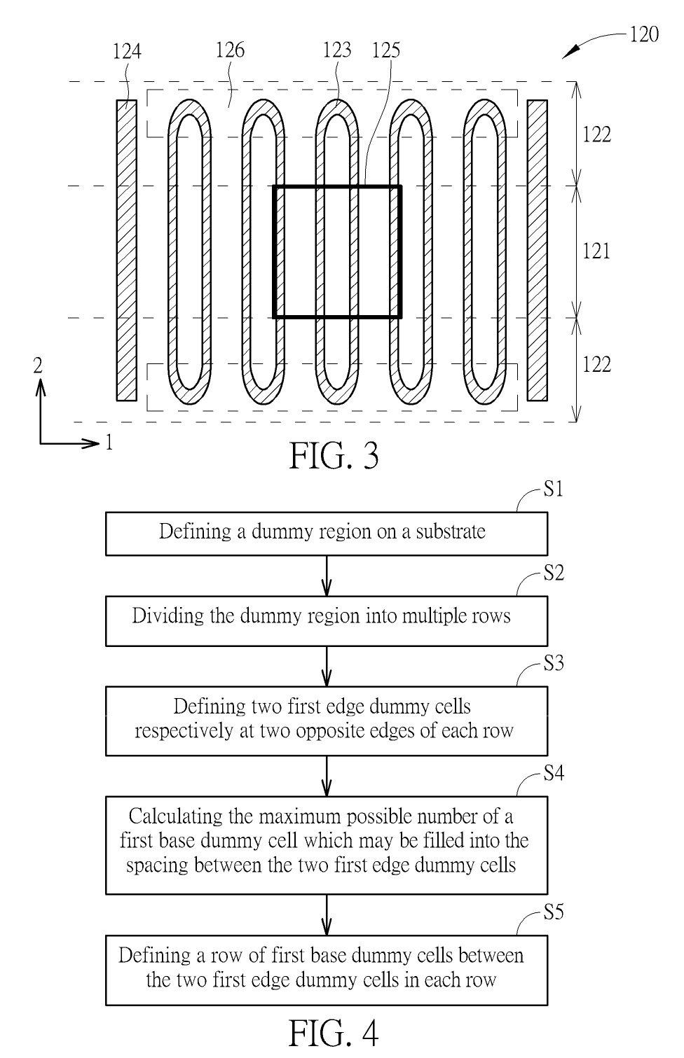

Please refer to FIG. 3, which is a schematic top view of dummy patterns arranged in the dummy cells of a column region 120 according to one embodiment of the present invention. An exemplary column region 120 with two inner second base dummy cells 121 and two outer second edge dummy cells 122 is provided in the embodiment to explicitly describe the dummy pattern arrangement of the present invention. Please note that the number of the second base dummy cells 121 may be different depending on, for example, the length of the column region 120 or the dimension of underlying active region to be overlapped.

As shown in FIG. 3, each second base dummy cell 121 two second edge dummy cells include a plurality of common line patterns 123 and 124 spaced apart from each other along the first (row) direction 1 and extending through the second base dummy cells 121 and the two second edge dummy cells along the second (column) direction 2, but not limited thereto. The common line patterns include a plurality of line patterns 123 with smaller width and a plurality of line patterns 124 with larger width at two opposite sides of said plurality of line patterns 123 with smaller width. Similarly, in the embodiment, the line patterns 123 with smaller width in the figure are depicted in a closed loop formed by sidewall image transfer (SIT) technology. The loop patterns formed by SIT may be further trimmed with additional mask 126 and etching process to remove the rounded, connected portions, so that each loop pattern is divided into two line patterns 123.

In the embodiment, the line patterns 123 are exemplarily assumed as the poly-Si lines for gate structures. In this case, the number of the second base dummy cells 121 filled in a column region 120 highly depends on the dimensions of the underlying active fin region 125, which may further depend on the number of fins extending along the first direction 1 in the active fin region 125. The second base dummy cells 121 are configured to cover the whole fin region 125. The fin regions 125 with longer length in column direction 2 would require more second base dummy cells 121 arranged in column direction 2 to cover thereon.

Different from the line patterns 113 in first base dummy cell 111, the line patterns 123 in the second base dummy cell 121 are common lines which may extend through all second base dummy cells 121 in a column region 120. The number of the second base dummy cells 121 in a column region 120 influence the length of the line patterns 123.

It should be noted that the present invention is not limited to the patterns of poly-Si line in the embodiment. The concept of extended dummy cell with line patterns in the present invention may be applied to any suitable dummy filling situation to provide flexible dummy cell filling. The dummy density may also be properly controlled corresponding to the adjacent circuit region through the arrangement of line patterns in dummy cells.

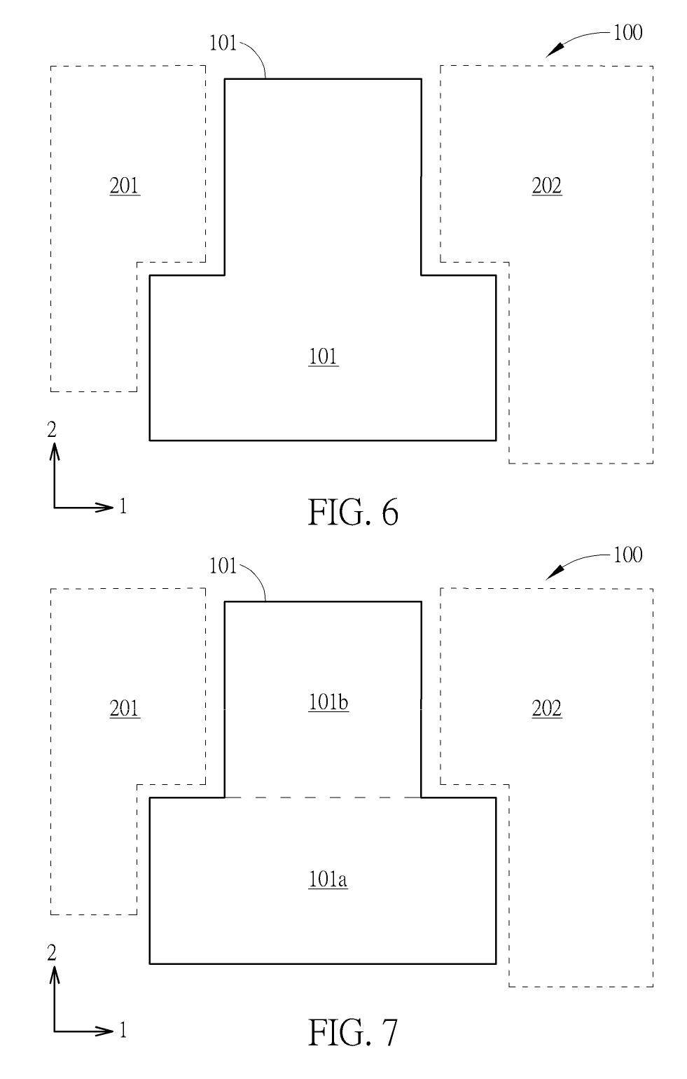

Hereinafter, a method of arranging dummy patterns in semiconductor devices according to an embodiment of the present invention will be described with reference to FIGS. 7 to 10, which are top views schematically illustrating the dummy cell placement and arrangement of the present invention. The present invention provides two arranging method for dummy cells. The first method is directed to fill the dummy region with a simple uniaxial configuration (only row regions). The second method is directed to fill the dummy region with a combination of biaxial configuration (both row regions and column regions), which may improve the filling condition and provide better dummy pattern density and uniformity.

It should be noted that, to form sophisticated patterns, artificial pattern manipulations such as optical proximity correction (OPC) would be applied to solve such difficulties. A technique wherein dummy patterns are interposed between main patterns has been used. This technique aims to prevent the occurrence of size differences of patterned structures according to the density of the main patterns during a photolithographic and/or etching process. The mask formed for a design layer may have M original design features and N original dummy features. The OPC program is typically run on characteristic data sets of the M original design features and the N original dummy features resulting in OPC-applied characteristic data sets. The mask is formed from the OPC-applied characteristic data sets of the M OPC-applied design features, and the N OPC-applied dummy features.

First, please refer to FIG. 4, which is a flow chart of a method of arranging dummy patterns in semiconductor devices according to one embodiment of the present invention. The method features a simple uniaxial arrangement for the dummy cell to be filled in the dummy region. In step S1, as shown in FIG. 6, the method starts from the step of defining a dummy region 101 on a substrate 100. The size and shape of the dummy region 101 depends on the adjacent circuit regions 201, 202.

Next in step S2, as shown in FIG. 7, the dummy region 101 is divided into a row dummy region 101a configured to fill dummy cell in rows and a column dummy region 101b configured to fill dummy cells in columns. It should be noted that the embodiment exemplifies a dummy region 100 with a simple inverted-T shape for better understanding. A sophisticated dummy region in real implementation is generally divided into multiple row dummy regions 101a and multiple column dummy regions 101b. The process of artificial pattern manipulations would determine the numbers, the positions, and the dimensions of the row dummy regions 101a and the column dummy regions 101b to be formed and divided from the dummy region 101.

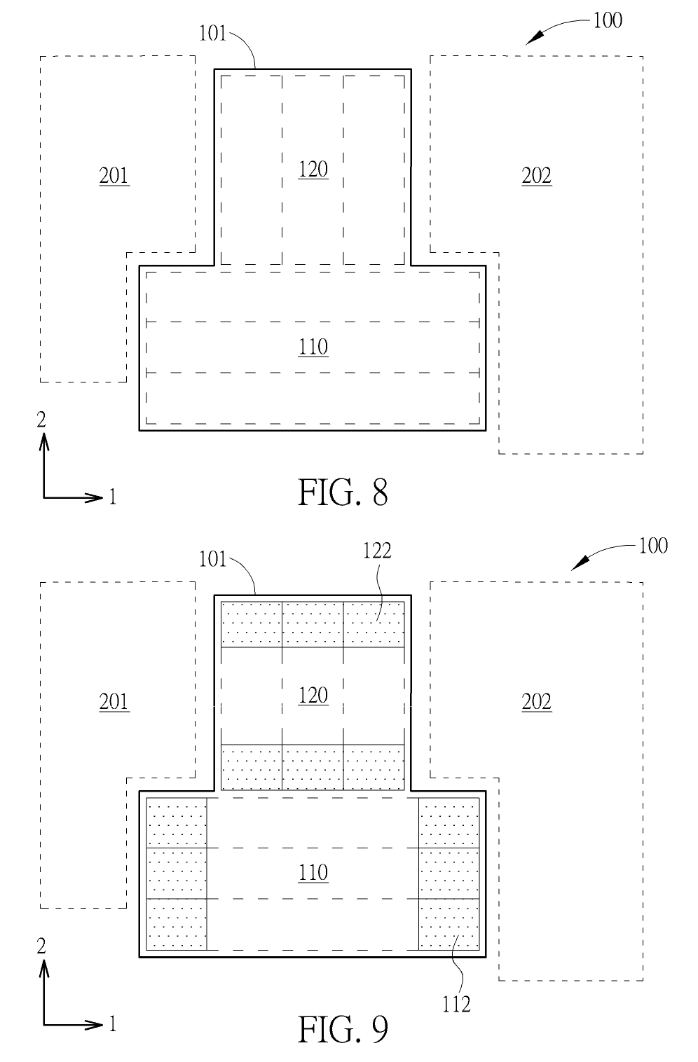

After the row dummy region 101a is defined, please refer to FIG. 8, the row dummy region 101a is divided into multiple row regions 110. The number of the row regions 110 in each row dummy region 101a may depend on the length of the mandrels patterns to be transferred into the line patterns in dummy cell or the design rule.

Next in step S3, please refer to FIG. 9, each row region 110 is defined with two first edge dummy cells 112 respectively at two opposite edges of the row region 110 in row direction 1. In the present invention, the edge dummy cells are fixed dummy cells arranged at an outermost edge to provide wider and solid dummy patterns between the dummy region 101 circuit regions 201, 202.

Next in step S4, the maximum possible number of the first base dummy cells 111 which may fill into the spacing between the two first edge dummy cells 112 is calculated. The width of the first base dummy cell 111 in row direction determines the number of the base dummy cell to be filled. In the present invention, as shown in FIG. 2, each first base dummy cell is included with two line patterns transformed from one mandrel by SIT process. It should be noted that the number of the line patterns 113 arranged in the base dummy cell is not particularly limited. The number of the line patterns 113 included in the base dummy cell depends on the desired dummy density, which may correspond to the pattern density of adjacent circuit regions 201, 202. It would also influence the width and the number of the first base dummy cell 111 included in a row region 110 in the embodiment.

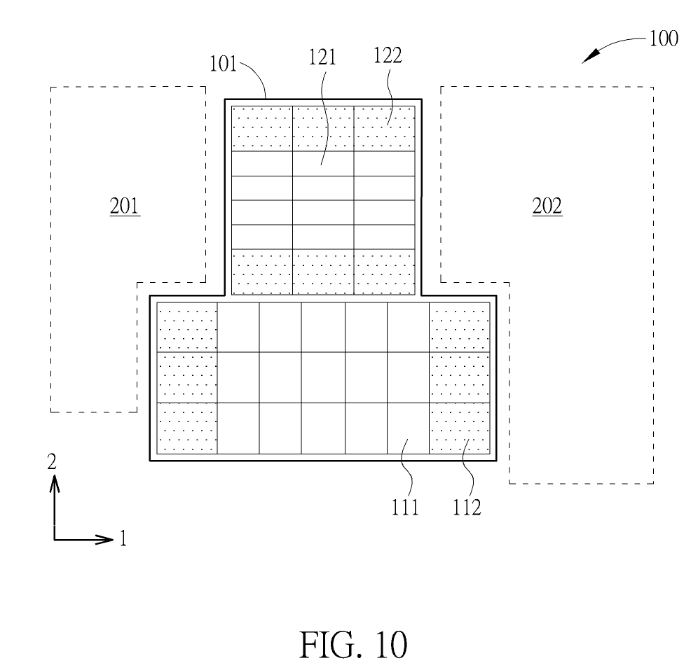

Next in step S5, please refer to FIG. 10, a row of first base dummy cells 111 is defined between the two first edge dummy cells 112 in each row based on the number calculated from step S4.

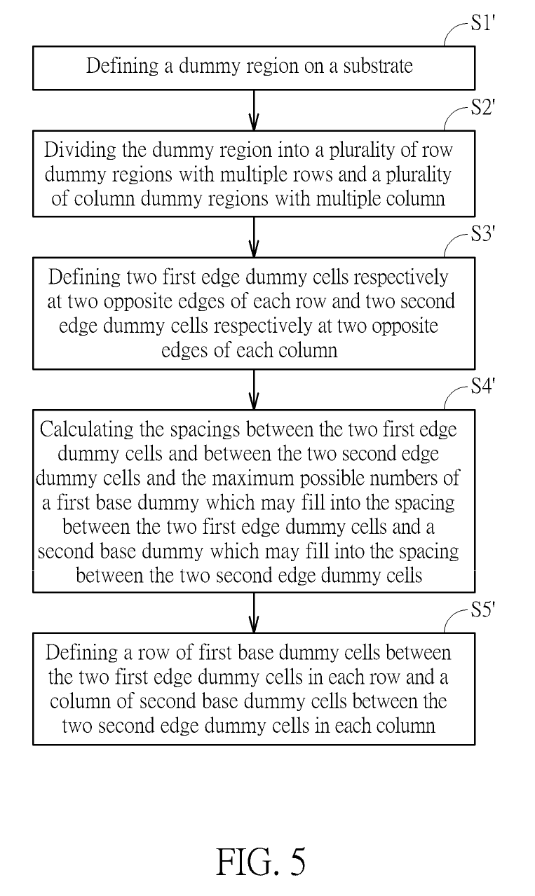

Hereinafter, an alternative method is provided to fill the dummy region with a combination of biaxial configuration (with both row regions and column regions). Please refer to FIG. 5, which is a flow chart of a method of arranging dummy patterns in semiconductor devices according to one embodiment of the present invention. The method features a biaxial arrangement for the dummy cell to be filled in the dummy region. In step S1′, similarly as shown in FIG. 6, the method starts from the step of defining a dummy region 101 on a substrate 100. The size and shape of the dummy region 101 depends on the adjacent circuit regions 201, 202.

Next in step S2′, as shown in FIG. 7, the dummy region 101 is divided into a row dummy region 101a configured to fill dummy cell in rows and a column dummy region 101b configured to fill dummy cells in columns. It should be noted that the embodiment exemplifies a dummy region 101 with a simple inverted-T shape for better understanding. A sophisticated dummy region in real implementation is generally divided into multiple row dummy regions 101a and multiple column dummy regions 101b. The process of artificial pattern manipulations would determine the numbers, the positions, and the dimensions of the row dummy regions 101a and the column dummy regions 101b to be formed and divided from the dummy region 101.

After the row dummy region 101a is defined, please refer to FIG. 8, the row dummy region 101a and the column dummy region 101b are divided respectively into multiple row regions 110 and multiple column regions 120. The number of the row regions 110 in each row dummy region 101a may depend on the length of the mandrels patterns to be transferred into the line patterns in dummy cell or the design rule, while the number of the column regions 120 in each column dummy region 101b may depend on the width of the dummy cell to be filled with, which may be further relating to the desired dummy density.

Next in step S3′, please refer to FIG. 9, each row region 110 and column region 120 is defined with two edge dummy cells 112, 122 respectively at two opposite edges in their row direction 1 or column direction 2. In the present invention, the edge dummy cell are fixed dummy cells arranged at an outermost edge to provide wider and solid dummy patterns between the dummy region 101 circuit regions 201, 202.

Next in step S4′, the maximum possible numbers of the first base dummy cells 111 and the second base dummy cells 111 which may fill respectively into the spacing between the two first edge dummy cells 112 and the two second edge dummy cells 122 are calculated. While the number of the first base dummy cells 111 to be filled primarily depends on the width of the first base dummy cell in row direction, the number of the second base dummy cells 121 to be filled primarily depends on the length of the mandrels to be transferred to the line patterns in SIT process. The shorter the length of the mandrel, the more the number of the second base dummy cells 121 to be filled in a column region 120. Several aligned mandrels may be merged into a long mandrel extending through all second base dummy cells 121 in a column region 120.

In FIG. 3, the number of the line patterns 123 arranged in the second base dummy cell 121 is not particularly limited. The number of the line patterns 113 included in the second base dummy cell depends on the desired dummy density, which may correspond to the pattern density of adjacent circuit regions 201, 202.

Next in step S5′, please refer to FIG. 10, a row of first base dummy cells 111 and a column of second base dummy cells 121 are defined respectively between the two first edge dummy cells 112 and the two second edge dummy cells 122 in each row region and column region based on the numbers calculated from the step S4′.

Those skilled in the art will readily observe that numerous modifications and alterations of the device and method may be made while retaining the teachings of the invention. Accordingly, the above disclosure should be construed as limited only by the metes and bounds of the appended claims.

1. A dummy pattern arrangement in a semiconductor device, comprising:
a substrate with a dummy region;
a plurality of first base dummy cells arranged along a first direction in said dummy region; and
two first edge dummy cells arranged respectively at two opposite sides of said plurality of first base dummy cells along said first direction in said dummy region and are fixed dummy cells between and adjacent to said plurality of first base dummy cells and circuit regions, wherein each said first base dummy cell and said first edge dummy cell comprises a plurality of line patterns spaced apart from each other along said first direction and extending in a second direction which is perpendicular to said first direction, and the width of said line patterns along said first direction in said first base dummy cell is smaller than the width of said line patterns in said first edge dummy cell.

2. (canceled)

3. The dummy pattern arrangement in a semiconductor device of claim 1, wherein said plurality of line patterns in said first base dummy cell are gate lines or fins.

4. The dummy pattern arrangement in a semiconductor device of claim 1, wherein said first edge dummy cells are fixed dummy cells arranged at an edge of said dummy region.

5. (canceled)

6. The dummy pattern arrangement in a semiconductor device of claim 1, further comprising a plurality of second base dummy cells arranged along said second direction in said dummy region and two second edge dummy cells arranged respectively at two opposite sides of said plurality of second base dummy cells along said second direction in said dummy region, wherein said plurality of second base dummy cells and two second edge dummy cells comprise a plurality of common line patterns spaced apart from each other along said first direction and extending through said plurality of second base dummy cells and said two second edge dummy cells along said second direction.

7. The dummy pattern arrangement in a semiconductor device of claim 6, wherein said common line patterns include a plurality of line patterns with smaller width and a plurality of line patterns with larger width at two opposite sides of said plurality of line patterns with smaller width.

8. The dummy pattern arrangement in a semiconductor device of claim 6, wherein said first base dummy cells, said first edge dummy cells, said second base dummy cells and said second edge dummy cells are arranged in columns and rows filling up said dummy region.

9. A method of arranging dummy patterns in semiconductor devices, comprising the steps of:
defining a dummy region on a substrate;
dividing said dummy region into multiple row regions;
defining two first edge dummy cells respectively at two opposite edges of each said row region; and
defining a first base dummy cell and a row of said first base dummy cells between said two first edge dummy cells in each said row region, wherein the number of said first base dummy cells in each said row region is a maximum possible number of said first base dummy cells which may fill up the space between said two first edge dummy cells in each said row region.

10. The method of arranging dummy patterns in semiconductor devices of claim 9, further comprising a step of dividing said dummy region into a plurality of row dummy regions with multiple said row regions and a plurality of column dummy regions with multiple columns.

11. The method of arranging dummy patterns in semiconductor devices of claim 10, further comprising a step of defining two second edge dummy cells respectively at two opposite edges of each said column and defining a second base dummy cell and a column of said second base dummy cells between two second edge dummy cells in each said column, wherein the number of said second base dummy cells in each said column is a maximum possible number of said second base dummy cells which may fill up the space between said two second edge dummy cells in each said column.

12. The method of arranging dummy patterns in semiconductor devices of claim 9, further comprising a step of calculating the circuit pattern density of a circuit region adjacent to said dummy region, and the line pattern density of said in said dummy region is configured as same as said circuit pattern density in said circuit region.

13. The method of arranging dummy patterns in semiconductor devices of claim 9, wherein each said first base dummy cell and said first edge dummy cell comprises a plurality of line patterns spaced apart from each other along the row direction.

14. The method of arranging dummy patterns in semiconductor devices of claim 9, wherein said line patterns in said first base dummy cell are formed through a sidewall image transfer process.
